(19) United States
(12) Patent Application Publication
(10) Pub. No.: US 2007/0261639 A1
(43) Pub. Date: Nov. 15, 2007

(54) SEMICONDUCTOR MANUFACTURING APPARATUS

(75) Inventors: Hitoshi MORIOKA, Tokyo (JP); Shigeo Ishikawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/738,971

(22) Filed: Apr. 23, 2007

(30) Foreign Application Priority Data
May 15, 2006 (JP) 2006-134703

(51) Int. Cl. H01L 21/02

(52) U.S. Cl. 118/715

(57) ABSTRACT

A semiconductor manufacturing apparatus is provided with a gas injection nozzle as a member made of aluminum nitride ceramics free from ittria (Y₂O₃) as a sintering agent. Since no ittrium (Y) is deposited on a surface of the nozzle, preferentially fluorinated portions are decreased. Therefore, adhesion with a precoating film is improved to thereby suppress generation of particles during deposition. Since the readily fluorinated portions are reduced, fluorination of the entire nozzle can be suppressed to thereby lengthen the life of the member. It is therefore possible to provide the semiconductor manufacturing apparatus capable of achieving a high operation rate and a high semiconductor production yield.

This application claims priority to prior Japanese patent application JP2006-134703, the disclosure of which is incorporated herein by reference.

### BACKGROUND OF THE INVENTION

This invention relates to a semiconductor manufacturing apparatus and, in particular, to a semiconductor manufacturing apparatus in which aluminum nitride is used in a gas injection (or inlet) nozzle for plasma-enhanced chemical vapor deposition.

In an apparatus for manufacturing a semiconductor device, ceramics materials are used for the purpose of avoiding metal contamination. Especially, for a gas injection nozzle, a stage for mounting a wafer thereon, a process chamber, and the like, the ceramics materials are often used. As the ceramics materials, aluminum nitride having high thermal conductivity is increasingly used. A manufacturing process of the semiconductor device includes many steps of depositing, as an insulating film, an oxidized silicon film on the wafer. These insulating films are deposited by plasma-enhanced chemical vapor deposition. Use is made of high-density plasma chemical vapor deposition (hereinbelow will be called HDP-CVD) which is especially excellent in filling (burying, or embedding) ability.

Referring to FIGS. 1A through 4, problems in deposition of the insulating film of the semiconductor device will be described with respect to each manufacturing step. As shown in FIG. 1A, a silicon nitride film 202 is deposited on a silicon substrate 201 to form a device isolating portion (Shallow Trench Isolation, STI). An aperture (or opening) width of the device isolating portion (STI) becomes narrower with the miniaturization of the semiconductor device. Therefore, when an STI isolating film is deposited, RF power of an HDP-CVD apparatus is increased in order to improve the filling ability. However, in case where the RF power is changed from approximately 4000-6000 W to approximately 7000-9000 W, plasma radiant heat increases. Consequently, the gas injection nozzle is heated to higher temperature and a phenomenon that particles during film deposition are increased in a short time is observed. Distribution of the particles has no specific pattern. The particles are observed even in the insulating film after the growth. Accordingly, it is understood that the particles are generated during a film deposition process.

Further, a ceramics gas injection nozzle after use was removed and a surface thereof was observed. In an outer circumference of the gas injection nozzle, a number of black spots were observed which are understood as corrosion by nitrogen trifluoride (NF₃) as cleaning gas (FIG. 5A). In such corroded part, adhesion is insufficient between the gas injection nozzle and a precoating film covering the gas injection nozzle. Therefore, it is conceivable that the precoating film peels off during the film deposition to cause generation of particles 203. In a state where the particles 203 are adhered (FIG. 1B), an HDP oxidized silicon film 204 is deposited by the HDP-CVD apparatus as shown in FIG. 1C. In this event, the HDP oxidized silicon film 204 is not deposited in a trench closed by the particles 203.

Most of the particles 203 are removed through a chemical mechanical polishing step (FIG. 2A), oxidized silicon film wet etching (FIG. 2B), and silicon nitride film wet etching (FIG. 2C). However, no HDP oxidized silicon film 204 is deposited in an area where the particles 203 are adhered. This area becomes a defective filling (embedding, or burying) portion. After various implantations and gate oxidization are performed, a gate polysilicon (doped poly-Si) film 205 is deposited. Then, the defective filling portion is completely filled (FIG. 2D). This results in short-circuiting between the silicon substrate 201 and the gate polysilicon film 205 so that a defective semiconductor device is produced. Accordingly, the production yield of the semiconductor device is decreased.

The particles are generated as a result of peeling of the precoating film from the corroded part of the gas injection nozzle corroded by the cleaning gas NF₃. It is noted here that the precoating film is an oxidized silicon film and is formed inside the apparatus in a preceding cycle of a series of deposition cycles. It has been understood that the peeling of the precoating film is caused particularly by insufficient cooling of a ceramics member during cleaning. Therefore, for the purpose of protection against corrosion, a sintering agent (generally, yttria (Y₂O₃)) for improving thermal conductivity of the ceramics member is used to increase a sintered density. Thus, the high-quality ceramics member is obtained to thereby achieve high cooling efficiency. However, in view of the fact that, in case where the RF power of the HDP-CVD apparatus is increased, the number of generated particles is large, the present inventor conducted the following study. FIGS. 3A and 3B show RF power dependency of the number of processed wafers and the number of particles. Specifically, FIGS. 3A and 3B show the number of particles at low RF power and high RF power, respectively. FIG. 4 shows the number of processed wafers and the number of particles.

Referring to FIGS. 3A and 3B, use was made of a gas injection nozzle comprising a member containing the sintering agent yttria (Y₂O₃). The number of particles generated under a high-RF-power deposition condition in a range approximately from 7000 to 9000 W was compared with that generated under a low-RF-power deposition condition in a range approximately from 4000 to 6000 W. It is noted here that those particles having a particle size not less than 0.18 μm were counted. As shown in FIG. 3A, 20 or less deposited particles were generated under the low-RF-power condition. As shown in FIG. 3B, in case where the same nozzle was used under the high-RF-power condition, the number of generated particles becomes extraordinarily large. Such phenomenon of extraordinary increase in number of generated particles depending upon the RF power frequently occurred. In the high-RF-power condition, the nozzle is heated in a short time and the deposition is performed at high process temperature to thereby increase the number of particles. Such a gas injection nozzle accompanied by generation of a large number of particles as shown in FIG. 3B has an initial failure and is not usable. Thus, even in an initial stage when the number of processed wafers is small, an extraordinarily large number of particles may be generated.

FIG. 4 shows the number of particles depending upon the number of processed wafers under the high-RF-power condition. With the increase of the number of processed wafers, the number of particles during deposition increases. When the number of processed wafers is approximately 500 to 600, the number of particles having a size not less than 0.16 μm is around 100. This means that the nozzle must be exchanged in an extremely short cycle. Presumably, the generation of the particles is attributed to the fact that sintered states of ceramics are different to thereby cause wide variation of a surface condition when the nozzle is manufactured. That is, under the high-RF-power condition, extremely wide variation of the surface condition causes a failure even at an initial stage of use of the nozzle. Next, it is understood that, with the increase of the number of processed wafers subjected to film deposition, fluorination is promoted to increase the number of particles. Thus, in the deposition under the high-RF-power condition of the HDP-CVD apparatus, there are problems that the production yield of the semiconductor is decreased by the increase of the number of particles and that the apparatus operation rate is decreased by the nozzle exchange in a short cycle.

There are the following documents related to aluminum nitride ceramics. In Japanese Unexamined Patent Application Publication (JP-A) No. 2003-261396, alumina is formed on a surface of aluminum nitride based ceramics so as to suppress corrosion by plasma. In Japanese Unexamined Patent Application Publication (JP-A) No. 2001-274103, aluminum nitride ceramics using yttria (Y₂O₃) as a sintering agent forms a gas shower. Further, in Japanese Unexamined Patent Application Publication (JP-A) No. S63-69761 and Japanese Unexamined Patent Application Publication (JP-A) No. S62-212267, a method of producing aluminum nitride ceramics using a sintering agent is disclosed.

### SUMMARY OF THE INVENTION

As mentioned above, the deposition under the high-RF-power condition of the HDP-CVD apparatus has problems that the production yield of the semiconductor is decreased by the increase of the number of particles and that the apparatus operation rate is decreased by the nozzle exchange in a short cycle. In view of the above-mentioned problems, it is an object of the present invention to provide a semiconductor manufacturing apparatus using, as a member, ceramics capable of suppressing generation of particles.

In order to solve the above-mentioned problems, the present invention basically employs techniques which will be mentioned hereinbelow. It is readily understood that the present invention encompasses applied technologies as various modifications without departing from the scope of the technical gist of the present invention.

That is, semiconductor manufacturing apparatuses according to this invention are as follows:

(1) A semiconductor manufacturing apparatus for use in plasma-enhanced chemical vapor deposition, the apparatus comprising a member which is exposed to plasma and heated to high temperature and which is formed by ceramics free from ittrium (Y) readily reacting with fluorine in order to suppress generation of particles.

(2) The semiconductor manufacturing apparatus as described in the above-mentioned (1), wherein the ceramics is one selected from the group of an oxide of metal which has a high thermal conductivity and which is hardly fluorinated and a nitride of the metal.

(3) The semiconductor manufacturing apparatus as described in the above-mentioned (2), wherein the metal is aluminum.

(4) The semiconductor manufacturing apparatus as described in the above-mentioned (1), wherein the member is a gas injection nozzle.

(5) A semiconductor manufacturing apparatus for use in plasma-enhanced chemical vapor deposition, the apparatus comprising a member which is exposed to plasma and heated to high temperature and which is formed by ceramics free from a sintering agent readily reacting with fluorine in order to suppress generation of particles.

(6) The semiconductor manufacturing apparatus as described in the above-mentioned (5), wherein the ceramics is one selected from the group of an oxide of metal which has a high thermal conductivity and which is hardly fluorinated and a nitride of the metal.

(7) The semiconductor manufacturing apparatus as described in the above-mentioned (5), wherein the member is a gas injection nozzle.

(8) The semiconductor manufacturing apparatus as described in the above-mentioned (5), wherein the sintering agent is one selected from the group of ittria (Y₂O₃), magnesia (MgO), calcia (CaO), strontium oxide (SrO), barium oxide (BaO), and lanthanum oxide (La₂O₃).

The semiconductor manufacturing apparatus of the present invention for use in the plasma-enhanced chemical vapor deposition is provided with the gas injection nozzle as a member made of aluminum nitride ceramics free from yttria (Y₂O₃) as a sintering agent. Since no yttrium (Y) is deposited on a surface of the nozzle, preferentially fluorinated portions are decreased and adhesion with a precoating film is improved. It is therefore possible to suppress generation of particles during deposition. Further, since the easily fluorinated portions are reduced, fluorination of the entire nozzle can be suppressed to thereby lengthen a life of the member. According to the present invention, it is possible to obtain the semiconductor manufacturing apparatus which has a high apparatus operation rate by prolonging a nozzle exchanging cycle and has a high semiconductor production yield by suppressing generation of the particles.

### BRIEF DESCRIPTION OF THE DRAWING

FIGS. 1A to 1C are sectional views of a semiconductor apparatus in order to describe influences of particles in a sequence of steps in a process of manufacturing a semiconductor device;

FIGS. 2A to 2D are sectional views similar to FIGS. 1A to 1C;

FIGS. 3A and 3B show RF power dependency of the number of processed wafers and the number of particles in a conventional technique under a low-RF-power condition and a high-RF-power condition, respectively;

FIG. 4 is a view showing the number of processed wafers and the number of particles in the conventional technique;

FIG. 5A is a schematic view of a gas injection nozzle in the conventional technique;

FIG. 5B is a graph showing an element analysis result in a fluorinated region;

FIG. 5C is a graph showing an element analysis result in an unfluorinated region;

FIG. 6 is a view showing temperatures (calculated values) of the gas injection nozzle at various RF power levels;

FIG. 7 is a view showing temperature-dependency of thermal conductivity of aluminum nitride.

FIG. 8 is a schematic view of an HDP-CVD apparatus;

FIG. 9 is a view showing the number of processed wafers and the number of particles in the present invention;

FIG. 10A is a schematic view of a gas injection nozzle; and

FIG. 10B shows an element analysis result in the present invention.

### DESCRIPTION OF THE PREFERRED EMBODIMENT

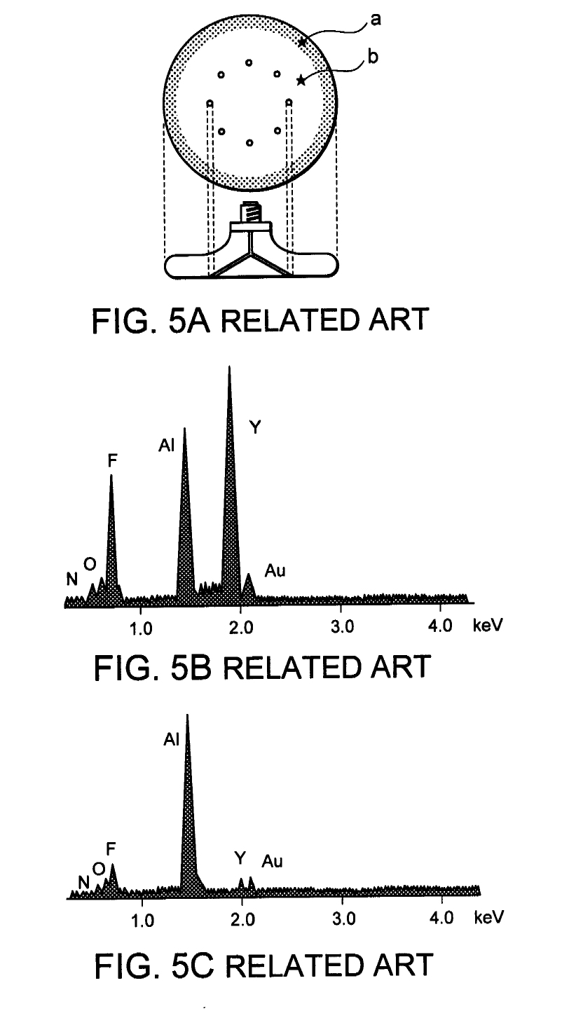

Now, referring to FIGS. 5 through 10, a semiconductor manufacturing apparatus of the present invention will be described in detail.

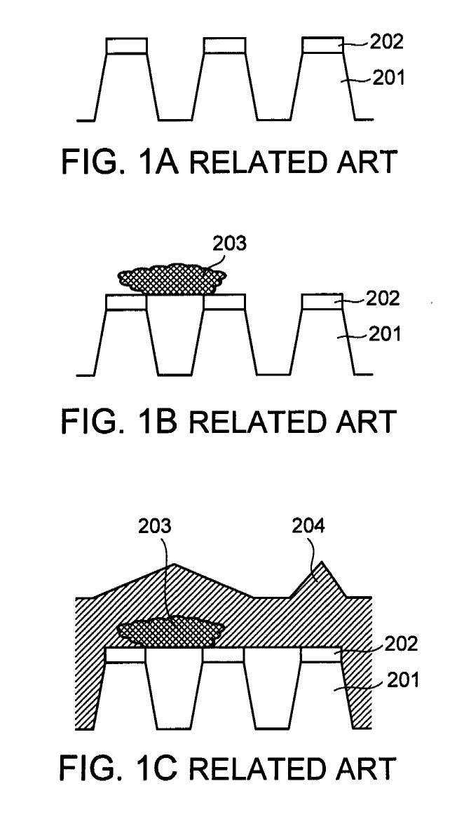

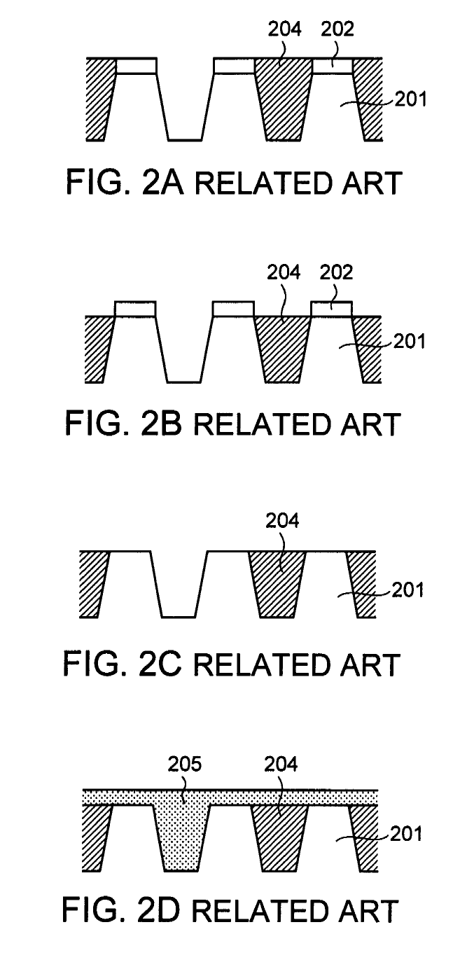

First, description will be made about a result of study performed by the present inventor and a particle-generating mechanism in an HDP-CVD apparatus on the basis of the result. The present inventor performed observation of a corroded portion of a ceramics nozzle exposed to plasma and analysis of elements. As shown in FIG. 5A, the gas injection nozzle is provided with a plurality of gas injection holes formed inside. In the outer circumference of the gas injection nozzle, a corroded region (dotted region) a is observed. Element analysis results in the corroded region a and an uncorroded region b are shown in FIGS. 5B and 5C, respectively. Comparison will be made between these analysis results. In FIG. 5C showing the element analysis result in the uncorroded region b, the amount of each of fluorine (F) and yttrium (Y) is very small. On the other hand, in FIG. 1B showing the element analysis result in the corroded region a, large amounts of fluorine (F) and yttrium (Y) are detected. In the corroded region, fluorine (F) and yttrium (Y) react with each other.

It is assumed that, in the corroded region a, yttrium (Y) is deposited on a surface of ceramics and reacts with NF₃ as cleaning gas to bring about progress of corrosion. In the corroded region, fluorination of yttrium (Y) locally progresses and the surface of ceramics is roughened into an uneven surface. Thus, fluorination of yttrium (Y) progresses and the surface of ceramics is roughened to thereby cause insufficient adhesion of a precoating film. As a result, the precoating film peels off to cause generation of particles.

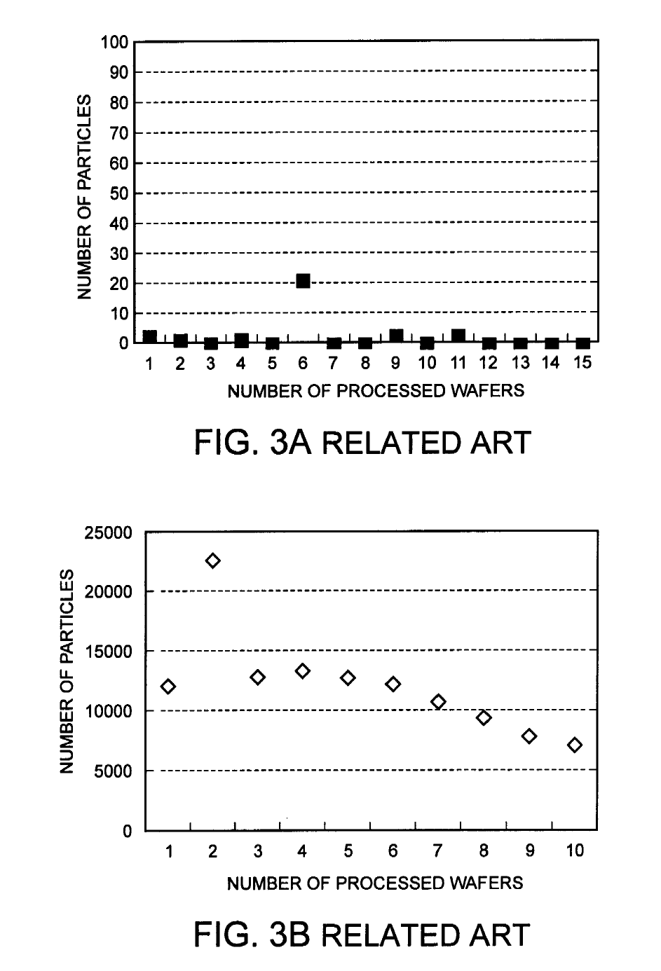

As described above, it is understood that fluorination is accelerated by the sintering agent for increasing the thermal conductivity of the ceramics. Aluminum nitride ceramics is produced by mixing aluminum nitride and the sintering agent to produce a mixture, agitating the mixture, and then sintering the mixture. Such agitation causes nonuniformity in mixing of aluminum nitride and the sintering agent and the nonuniformity is large. This brings about wide variation in deposition of the sintering agent yttria (Y₂O₃) on the surface of the ceramics member. Consequently, even with a new nozzle as shown in FIG. 3B, a large number of particles are generated to cause an initial failure if nonuniformity in mixing is large.

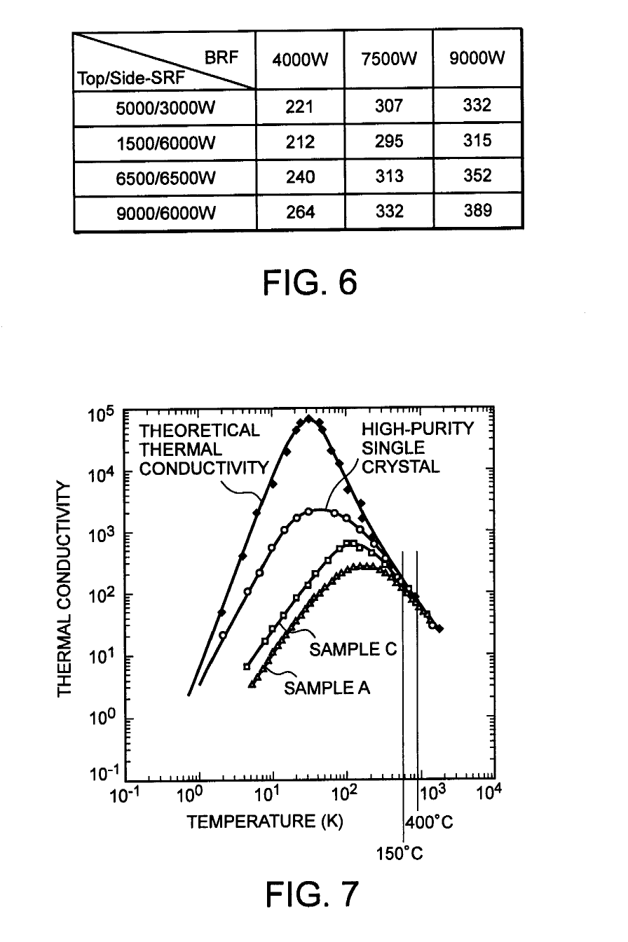

Next, FIG. 6 shows temperatures of the gas injection nozzle at high-frequency powers applied to the HDP-CVD apparatus. The temperatures are obtained by calculation as temperatures of the gas injection nozzle at various BRF (Bias Radio Frequency) powers and various SRF (Source Radio Frequency) powers. When the temperature is elevated to 300° C. or higher at the RF powers, generation of corroded (fluorinated) regions and generation of particles become remarkable. FIG. 7 shows theoretical thermal conductivity of aluminum nitride and thermal conductivity of each of high-purity single crystal, a sample C (containing the sintering agent yttria (Y₂O₃)), and a sample A (without the sintering agent). At low temperature, the thermal conductivity of the sample C is larger than that of the sample A and, therefore, the effect of the sintering agent is confirmed. However, no effect upon the thermal conductivity is observed in a temperature range of 150 to 400° C. at which the semiconductor manufacturing apparatus is used. In case where process temperature rises by radiant heat of high RF power, there is no significant difference between the thermal conductivity and the theoretical value irrespective of material quality.

Thus, the sintering agent introduced for the purpose of improving the thermal conductivity exhibits no effect at the process temperature and, to the contrary, promotes fluorination to cause generation of particles. In case where ittrium (Y) as the sintering agent is deposited on the surface of the nozzle and, during cleaning, a portion where ittrium (Y) is deposited is exposed to plasma containing fluorine radical, the portion is preferentially fluorinated. The fluorinated portion degrades adhesion with a precoating film and the precoating film peels off as particles on a wafer during film deposition. This results in occurrence of a defect. In the HDP-CVD apparatus, in order to improve the filling (burying, or embedding) ability, RF power is increased. At high temperature under such high-RF-power condition, improvement of thermal conductivity by presence of the sintering agent ittria (Y₂O₃) is not expected. To the contrary, the sintering agent and cleaning gas react with each other to accelerate the progress of corrosion. This causes generation of the particles. In view of the above, in order to suppress generation of the particles, ceramics using no sintering agent is considered.

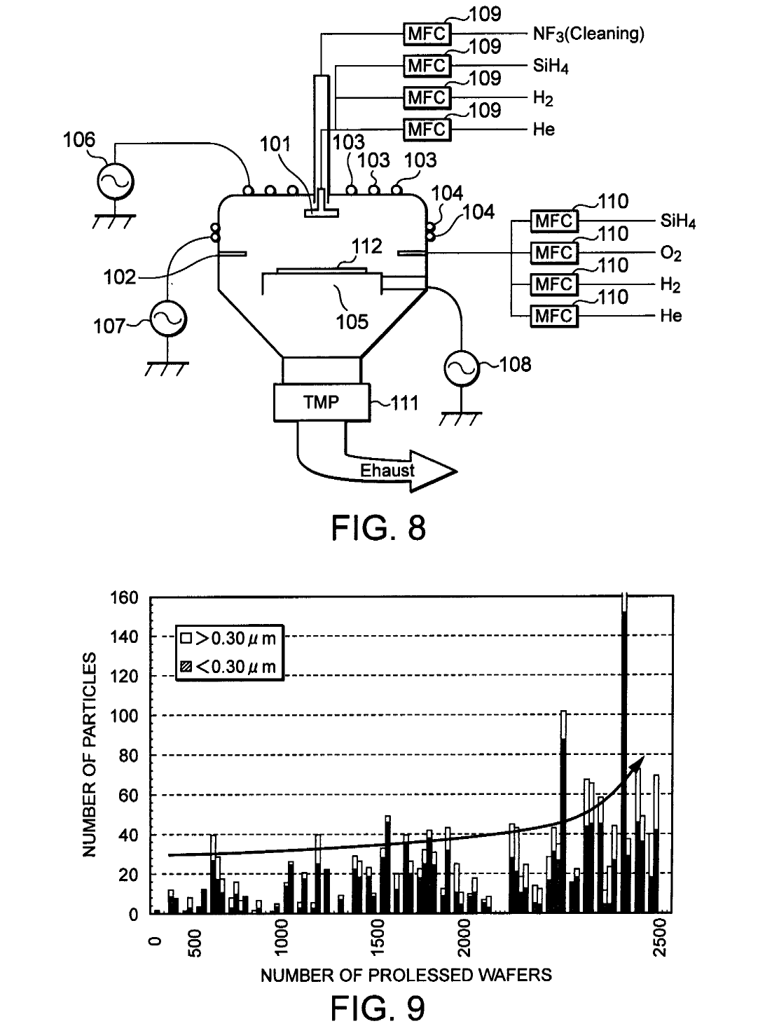

Next referring to FIG. 8, the HDP-CVD apparatus will be described. The HDP-CVD apparatus has an upper gas injection nozzle 101 formed above a wafer stage 105 and chamber side wall gas injection nozzles 102 formed on side walls of a chamber and extending toward the center of a wafer 112. Via the upper gas injection nozzle 101 and the chamber side wall gas injection nozzles 102, gas is uniformly introduced into the chamber. An upper source coil 103 and a chamber side wall source coil 104 are wound around the chamber of a ceramic dome. The upper source coil 103 and the chamber side wall source coil 104 are supplied with high frequency power by an upper source high-frequency power supply 106 and a chamber side wall source high-frequency power supply 107 to generate source plasma, respectively.

The wafer stage 105 on which the wafer 112 is mounted has an electrostatic chuck (ESC) so that high frequency power is applied to the stage 105 from a substrate bias high-frequency power supply 108. Through the upper gas injection nozzle 101, several kinds of gases controlled in flow rate by an upper gas mass flow controller 109 are introduced. Through the chamber side wall gas injection nozzles 102, several kinds of gases controlled in flow rate by a side wall gas mass flow controller 110 are introduced. The chamber has an exhaust port connected to a turbo-molecular pump (TMP) 111 which controls the degree of vacuum inside the chamber.

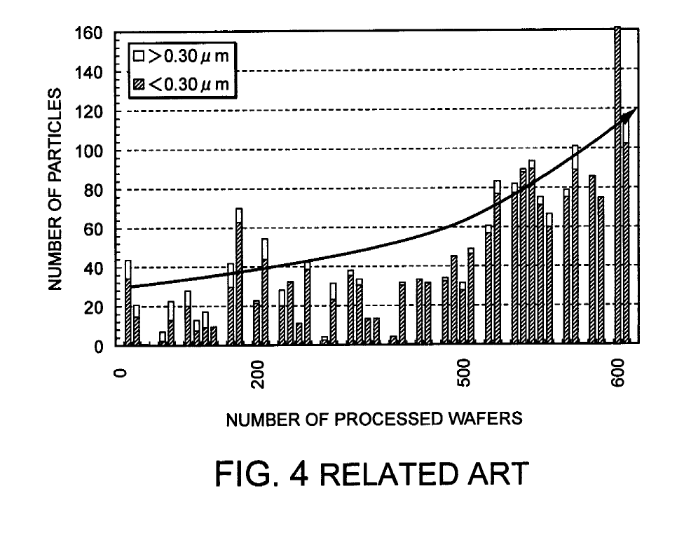

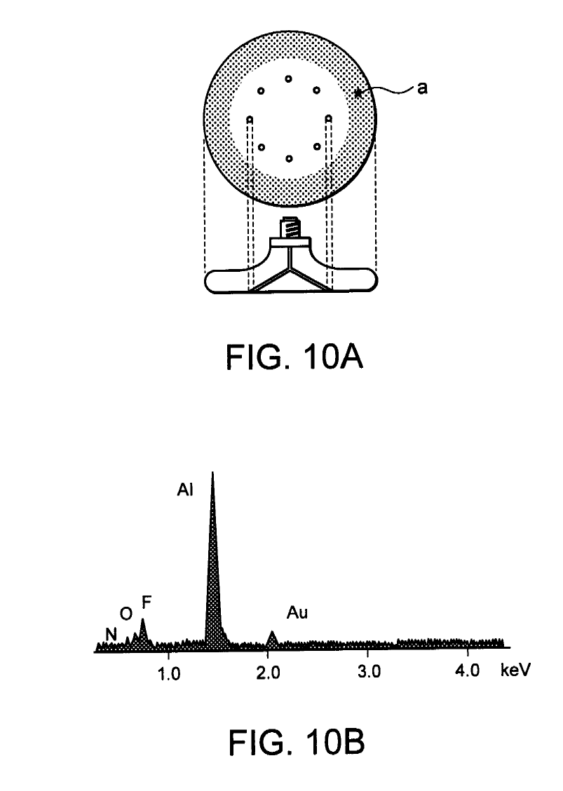

In the HDP-CVD apparatus, aluminum nitride AlN containing no sintering agent ittria (Y₂O₃) is used as a material of the upper gas injection nozzle 101. In this case, the results shown in FIGS. 9, 10A and 10B are obtained. Referring to FIG. 9, the number of particles (having a particle size of 0.16 μm or more) is suppressed to approximately 40 or less and no drastic increase is observed until the number of processed wafers slightly exceeds 2000. In comparison with the conventional example shown in FIG. 4, the number of processed wafers without generation of an extraordinarily large number of particles is four to five times. FIG. 10A shows the gas injection nozzle and FIG. 10B shows an element analysis result obtained by the use of fluorescent X-ray. The analysis result is data of the upper gas injection nozzle 101 when the number of processed wafers exceeds 2500.

Referring to FIG. 10A, a surface of an outer circumferential portion of the gas injection nozzle is fluorinated and roughened over a wider area. Since no ittrium (Y) as the sintering agent is deposited on the surface of the nozzle, preferentially fluorinated portions are decreased and fluorination uniformly progresses throughout the whole nozzle. A fluorinated region becomes wider with the increase of the number of processed wafers. However, the roughness is uniformly small and the surface condition is different from the state in which fluorination locally progresses as in the conventional example. FIG. 10B shows the analysis result for a fluorinated region a. It is understood that, in comparison with the conventional nozzle, the cleaning gas contains a small amount of fluorine (F) and a large amount of a fluorinated product is not present.

It is desired that the gas injection nozzle is made of a material which has high thermal conductivity and is hardly fluorinated. For example, alumina (Al₂O₃) and aluminum nitride (AlN) are preferable. Herein, the conventional material using the sintering agent may be used for a nozzle which is not exposed to plasma so that the temperature is not elevated or for a nozzle which extends away from the wafer so that no problem is caused even if the particles are generated. As a material for the gas injection nozzle which is exposed to plasma and heated to high temperature, aluminum nitride (AlN) containing no sintering agent ittria (Y₂O₃) is used. Although the gas injection nozzle is heated to high temperature, no reaction between the sintering agent and the cleaning gas occurs since no sintering agent is contained therein. It is therefore possible to prevent initial failure due to nonuniformity in mixing of the sintering agent and corrosion due to the sintering agent ittria (Y₂O₃) and the cleaning gas. Fluorination under the high-RF-power condition is suppressed to thereby suppress the generation of particles.

In the present invention, as the material for the gas injection nozzle which is heated to high temperature, aluminum nitride (AlN) is used which contains no ittria (Y₂O₃) as the sintering agent. Thus, the material of ceramics is changed so as to suppress reaction with the cleaning gas. Since no ittrium (Y) is deposited on the surface of the nozzle, preferentially fluorinated portions are decreased and adhesion with a precoating film is improved. It is therefore possible to suppress generation of particles during deposition. Further, since the easily fluorinated portions are reduced, fluorination of the entire nozzle can be suppressed to thereby lengthen a life of the member. This makes it possible to decrease the rate of initial failure of the gas injection nozzle and to suppress generation of deposition particles. As a consequence, it is confirmed that the frequency of regular maintenance of the apparatus is decreased and the production yield of semiconductor is improved.

In the embodiment, the upper gas injection nozzle fixed above the wafer is described. However, the ceramics nozzle of the present invention is applicable to a nozzle having a structure in which gas is introduced above the wafer, for example, a side wall gas injection nozzle having a length extending from the side wall of the chamber to a position above the wafer. Further, as the sintering agent, not only ittria (Y₂O₃) but also magnesia (MgO), calcia (CaO), strontium oxide (SrO), barium oxide (BaO), and lanthanum oxide (La₂O₃) are used. These sintering agents more readily react with fluorine as compared with metals as a main component of ceramics. Therefore, the sintering agent and fluorine locally react with each other to generate particles.

It is therefore preferable to use, as a member of the gas injection nozzle, ceramics free from these sintering agents which readily react with fluorine. Herein, to readily react with fluorine is in comparison with the main component of ceramics. For example, in case where the sintering agent ittria (Y₂O₃) is used in aluminum nitride (AlN) ceramics, ittria (Y₂O₃) more readily reacts with fluorine than aluminum nitride (AlN). Therefore, use of ittria (Y₂O₃) promotes fluorination to cause generation of particles.

In the semiconductor manufacturing apparatus of the present invention, use is made of an aluminum nitride (AlN) gas injection nozzle which does not contain ittria (Y₂O₃) as the sintering agent. Since no ittrium (Y) is deposited on the surface of the nozzle, preferentially fluorinated portions are decreased and adhesion with a precoating film is improved. It is therefore possible to suppress generation of particles during deposition. Further, since the easily fluorinated portions are reduced, fluorination of the entire nozzle can be suppressed to thereby lengthen the life of the member. By suppressing generation of particles, it is possible to obtain the semiconductor manufacturing apparatus capable of reducing the frequency of regular maintenance of the apparatus and improving the production yield of the semiconductor.

In the foregoing, the present invention has been described in detail in connection with the preferred embodiment. However, it will readily be understood that the present invention is not limited to the above-mentioned embodiment but may be modified in various manners without departing from the scope of the present invention and these modifications are included in the present invention.

What is claimed is:

1. A semiconductor manufacturing apparatus for use in plasma-enhanced chemical vapor deposition, said apparatus comprising a member which is exposed to plasma and heated to high temperature and which is formed by ceramics free from ittrium (Y) readily reacting with fluorine in order to suppress generation of particles.

2. The semiconductor manufacturing apparatus as claimed in claim 1, wherein said ceramics is one selected from the group of an oxide of metal which has a high thermal conductivity and which is hardly fluorinated and a nitride of said metal.

3. The semiconductor manufacturing apparatus as claimed in claim 2, wherein said metal is aluminum.

4. The semiconductor manufacturing apparatus as claimed in claim 1, wherein said member is a gas injection nozzle.

5. A semiconductor manufacturing apparatus for use in plasma-enhanced chemical vapor deposition, said apparatus comprising a member which is exposed to plasma and heated to high temperature and which is formed by ceramics free from a sintering agent readily reacting with fluorine in order to suppress generation of particles.

6. The semiconductor manufacturing apparatus as claimed in claim 5, wherein said ceramics is one selected from the group of an oxide of metal which has a high thermal conductivity and which is hardly fluorinated and a nitride of said metal.

7. The semiconductor manufacturing apparatus as claimed in claim 5, wherein said member is a gas injection nozzle.

8. The semiconductor manufacturing apparatus as claimed in claim 5, wherein said sintering agent is one selected from the group of ittria (Y₂O₃), magnesia (MgO), calcia (CaO), strontium oxide (SrO), barium oxide (BaO), and lanthanum oxide (La₂O₃).
